(19) United States
(12) Patent Application Publication
(10) Pub. No.: US 2026/0271584 A1
(43) Pub. Date: Sep. 10, 2026

(54) SUPPORT STRUCTURE, DISPLAY MODULE, AND DISPLAY DEVICE

(71) Applicant: BOE Technology Group Co., Ltd., Beijing (CN)

(72) Inventors: Ziang HAN, Beijing (CN); Zihan GAO, Beijing (CN); Zhao LI, Beijing (CN); Meiling GAO, Beijing (CN); Qiang XIE, Beijing (CN); Zhihao XIE, Beijing (CN)

(21) Appl. No.: 19/480,004

(22) PCT Filed: Dec. 11, 2024
(86) PCT No.: PCT/CN2024/138605

§ 371 Date: Oct. 29, 2025

(30) Foreign Application Priority Data
Jan. 29, 2024 (CN) 202410122369.3

(51) Int. Cl. H10K 59/80; H10K 77/10; H10K 102/00

(52) U.S. Cl. CPC H10K 59/871; H10K 77/111; H10K 2102/311; H10K 2102/351

(57) ABSTRACT

Provided is a support structure, including a patterned layer, a metal layer, and a first organic layer that are sequentially stacked, wherein the patterned layer includes a bending region and flat regions, the flat regions are located on two opposite sides of the bending region, and the bending region is provided with a plurality of openings; and a thickness of the metal layer is less than a preset thickness, and an elastic modulus of the metal layer is greater than an elastic modulus of the first organic layer.

The present disclosure is a U.S. national stage of international application No. PCT/CN2024/138605, which claims priority to Chinese Patent Application No. 202410122369.3, filed on Jan. 29, 2024 and entitled “SUPPORT STRUCTURE, DISPLAY MODULE, AND DISPLAY DEVICE”, the disclosure of which is herein incorporated by reference in its entirety.

### TECHNICAL FIELD

The present disclosure relates to the field of display technologies, and in particular, to a support structure, a display module, and a display apparatus.

### BACKGROUND

As the development of display apparatuses advances rapidly, fine adjustments of functions or structures are often made based on actual market demands. With the development of display technologies, various new forms of display devices have emerged in response to the ever-changing market needs. In order to balance the portability and display performance of mobile terminal electronic devices, relevant technologies have introduced flexible display devices of foldable and rollable types. Compared with flat rigid display devices, flexible display devices can be folded, rolled, or bent like paper, offering higher portability and convenience. At the same time, they can also achieve large-screen display when flattened.

### SUMMARY

The present disclosure provides a support structure, a display module, and a display device.

In some embodiments, a support structure is provided. The support structure includes a patterned layer, a metal layer, and a first organic layer that are sequentially stacked;
the patterned layer includes a bending region and flat regions, the flat regions are located on two opposite sides of the bending region, and the bending region is provided with multiple openings;
the thickness of the metal layer is less than a preset thickness, and the elastic modulus of the metal layer is greater than the elastic modulus of the first organic layer.

In some embodiments, the thickness of the metal layer is less than 30 μm.

In some embodiments, the elastic modulus of the metal layer is greater than 480 Gpa and less than 1 Tpa, and the elastic modulus of the first organic layer is greater than 10 Mpa and less than 5 Gpa.

In some embodiments, the elastic modulus of the metal layer is greater than the elastic modulus of the patterned layer.

In some embodiments, the elastic modulus of the patterned layer is greater than 70 Gpa and less than 150 Gpa.

In some embodiments, the tensile strength of the metal layer is greater than the tensile strength of the patterned layer.

In some embodiments, the tensile strength of the metal layer is greater than 1800 Mpa and less than 5 Gpa, and the tensile strength of the patterned layer is greater than 700 Mpa and less than 2 Gpa.

In some embodiments, the patterned layer is made of carbon fiber.

In some embodiments, the metal layer is made of at least one of steel use stainless, copper, or aluminum.

In some embodiments, the first organic layer is made of at least one of polymethyl methacrylate, polyimide, thermoplastic polyurethane rubber, or silicone.

In some embodiments, the thickness of the first organic layer is greater than 5 μm and less than 20 μm.

In some embodiments, the support structure further includes a second organic layer, and the second organic layer is located between the patterned layer and the metal layer;
the elastic modulus of the metal layer is greater than the elastic modulus of the second organic layer.

In some embodiments, thicknesses of the first organic layer, the second organic layer, and the metal layer satisfy at least one of the following conditions:
the ratio of the thickness of the first organic layer to the thickness of the metal layer is greater than ⅓ and less than ⅔; and
the ratio of the thickness of the second organic layer to the thickness of the metal layer is greater than ⅓ and less than ⅔.

In some embodiments, a display module is provided. The display module includes: a flexible display panel and the support structure according to any one embodiment of the foregoing aspect, wherein a side of the flexible display panel distal to a display surface is attached to the support structure;
the flexible display panel includes a bending region and flat regions, the orthographic projection of a bending region of a patterned layer in the support structure on the flexible display panel overlaps with the bending region on the flexible display panel, and the orthographic projection of flat regions of the patterned layer in the support structure on the flexible display panel overlaps with the flat regions on the flexible display panel.

In some embodiments, the flexible display panel includes a display layer and a flexible base substrate;
the patterned layer is located on a side of the flexible base substrate distal to the display layer, and a metal layer in the support structure is located between the patterned layer and the flexible base substrate.

In some embodiments, the display module further includes a first limiting structure, and the first limiting structure is located on a side of the support structure distal to the flexible display panel;
the first limiting structure is configured to limit the bending region of the patterned layer and the bending region of the flexible display panel to be in a first bent state or a flattened state;
in the first bent state, light-emitting surfaces of the flat regions on two sides of the bending region of the flexible display panel are opposite to each other, and the angle between the flat regions on the two sides is less than 180°;
the support structure includes the patterned layer, a second organic layer, the metal layer, and the first organic layer that are sequentially stacked, and the elastic modulus of the second organic layer is greater than the elastic modulus of the first organic layer.

In some embodiments, the display module further includes a second limiting structure, and the second limiting structure is located on a side of the support structure distal to the flexible display panel;
the second limiting structure is configured to limit the bending region of the patterned layer and the bending region of the flexible display panel to be in a second bent state or a flattened state;
in the second bent state, light-emitting surfaces of the flat regions on two sides of the bending region of the flexible display panel are opposite to each other in a back-to-back manner, and the angle between the flat regions on the two sides is less than 180°; and
the support structure includes the patterned layer, a second organic layer, the metal layer, and the first organic layer that are sequentially stacked, and the elastic modulus of the second organic layer is less than the elastic modulus of the first organic layer.

In some embodiments, a display device is provided. The display device includes the support structure according to any one of above embodiments or the display module according to any one of above embodiments.

### BRIEF DESCRIPTION OF DRAWINGS

FIG. 1 is a schematic cross-sectional view of a support structure according to some embodiments of the present disclosure;

FIG. 2 is a schematic plan view of a patterned layer according to some embodiments of the present disclosure;

FIG. 3 is a schematic cross-sectional view of another support structure according to some embodiments of the present disclosure;

FIG. 4 is a schematic cross-sectional view of yet another support structure according to some embodiments of the present disclosure;

FIG. 5 is a schematic flowchart of a method for manufacturing a support structure according to some embodiments of the present disclosure;

FIG. 6 is a schematic cross-sectional view of a display module according to some embodiments of the present disclosure;

FIG. 7 is a schematic cross-sectional view of another display module according to some embodiments of the present disclosure; and

FIG. 8 is a schematic cross-sectional view of yet another display module according to some embodiments of the present disclosure.

### DETAILED DESCRIPTION

To make the objectives, technical solutions, and advantages of the present disclosure clearer, the present disclosure is further described in detail below with reference to the accompanying drawings and embodiments. It should be understood that the specific embodiments described herein are intended to explain the present disclosure only rather than to limit the present disclosure.

A flexible display device enables a foldable display screen by using a flexible structure. However, due to the low rigidity, the flexible display device exhibits poor drop resistance and impact resistance, often failing to meet the requirements of practical applications. Therefore, how to improve the drop resistance and impact resistance of the flexible display device remains a problem to be solved for the realization of foldable display screens at present.

Relevant technologies propose using bendable support structures to provide structural support for flexible display devices. For example, carbon fiber plates or stainless steel plates (SUS) are used as support structures. However, if the support structure is made of materials such as carbon fiber, which are relatively soft and thin, it may not provide sufficient support. On the other hand, if the support structure is made of materials such as stainless steel, which are relatively hard and thick, it may affect the bending performance of the flexible display device—for instance, reducing the number of bendable times of the flexible display device or decreasing its maximum bendable angle.

If the carbon fiber plates and stainless steel plates are used together as the support structure of a flexible display device, the drop resistance of the flexible display device will be improved. However, to ensure bending performance, the thickness of the stainless steel plate needs to be set sufficiently small. When the thickness of the stainless steel plate is set to be sufficiently small, it is highly prone to developing wrinkles or surface scratches, which in fact will significantly reduce the number of bendable times of the flexible display device and lead to deterioration in its bending performance.

Based on this, embodiments of the present disclosure provide a support structure and a method for manufacturing the same, a display module, and a display device. The support structure provided in the embodiments of the present disclosure includes a patterned layer, a metal layer, and an organic layer that are stacked. The organic layer protects the metal layer, thus reducing wrinkles or scratches on the metal layer, and the patterned layer is provided with an opening hole to define a bending region, so that not only the mass productivity of the support structure is improved, but also the bending performance of the support structure is enhanced. The support structure provided in the embodiments of the present disclosure is applicable to various types of foldable devices, including but not limited to a foldable flexible display device, to support and secure the foldable device and improve the bending performance and impact resistance of the foldable device.

The embodiments of the present disclosure will be explained below with reference to the accompanying drawings.

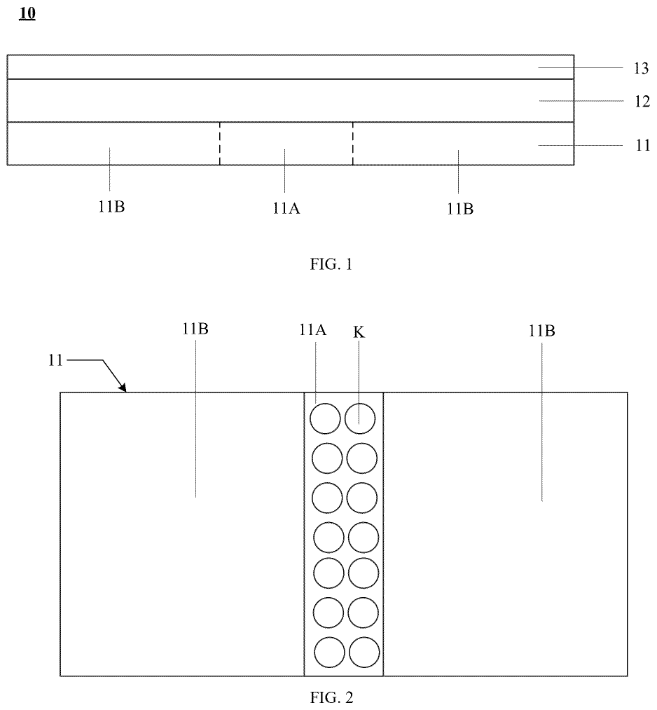

For example, FIG. 1 is a schematic cross-sectional view of a support structure according to some embodiments of the present disclosure. As shown in FIG. 1, a support structure 10 includes a patterned layer 11, a metal layer 12, and a first organic layer 13 that are sequentially stacked. The first organic layer 13 protects the metal layer 12. The patterned layer 11 and the metal layer 12 play a role of structural support.

FIG. 2 is a schematic planar view of a patterned layer according to some embodiments of the present disclosure. As shown in FIG. 2, the patterned layer 11 includes a bending region 11A and flat regions 11B. The flat regions 11B are located on two opposite sides of the bending region 11A. The bending region 11A is provided with multiple openings K. The bending region may also be referred to as a folding region and provides a bending or folding function. The flat region may also be referred to as a non-folding region and provides a support function as a flat.

In the embodiments of the present disclosure, by providing the openings in the bending region 11A of the patterned layer 11, the patterned layer 11 is effectively made easier to bend in the bending region 11A, thereby reducing the fatigue degree of the material of the patterned layer 11.

In some embodiments, referring to FIG. 2, the bending region 11A of the patterned layer 11 is rectangular. For example, the bending region 11A is a rectangular region provided with patterned openings K or openings K arranged in an array.

In some embodiments, the multiple openings K in the bending region 11A of the patterned layer 11 include, but are not limited to, one or more of rectangular openings, circular openings, or elliptical openings. In some embodiments, the multiple openings K in the bending region 11A of the patterned layer 11 include through holes and/or non-through holes.

In addition, in the support structure 10 provided by the embodiments of the present disclosure, the thickness of the metal layer 12 is less than a preset thickness. The elastic modulus of the metal layer 12 is greater than the elastic modulus of the first organic layer 13.

In the embodiments of the present disclosure, by using the relatively thin metal layer 12 with high material strength, the metal layer cooperates with the patterned layer 11 to provide structural support and cooperates with the bending region 11A of the patterned layer 11 to achieve overall bendability of the support structure. In some embodiments, the preset thickness is 30 micrometers (μm). That is, the thickness of the metal layer 12 is less than 30 μm. In some embodiments, the thickness of the metal layer 12 ranges from 15 μm to 30 μm. For example, the thickness of the metal layer 12 is 20 μm. In some embodiments, the elastic modulus of the metal layer 12 is greater than 480 gigapascals (Gpa) and less than 1 terapascal (Tpa).

In the embodiments of the present disclosure, by using the first organic layer 13 with a low elastic modulus, the protection for the metal layer 12 and its resistance against wrinkling are achieved. In some embodiments, the elastic modulus of the first organic layer 13 is greater than 10 megapascals (Mpa) and less than 5 Gpa.

In some embodiments, the elastic modulus of the metal layer 12 is not equal to the elastic modulus of the patterned layer 11. This enables both the bending performance and the support performance of the support structure to be balanced.

In the embodiments of the present disclosure, the bending performance is quantified by the number of bendable service life cycles of the bending region or the maximum recoverable bending angle. For example, the more bendable service life cycles the bending region has or the larger the maximum recoverable bending angle is, the stronger the bending performance will be. The bending performance of a film layer is usually positively correlated with the elastic modulus of the film layer material; the higher the elastic modulus of the film layer material, the stronger the bending performance of the film layer.

In the embodiments of the present disclosure, the support performance is quantified by the strength of the flat region. For example, the higher the strength of the flat region, the stronger the support performance. In some embodiments, the strength of the flat region is represented by at least one of the following: tensile strength, yield strength, compressive strength, shear strength, flexural strength, or impact strength. The greater the tensile strength, the higher the strength of the material.

It is worth noting that, in the embodiments of the present application, for the features to be quantified (such as elastic modulus, tensile strength, etc.), unless otherwise specified, when the feature itself is used to characterize the inherent properties of a material, the feature of the target object is used to characterize the corresponding feature of the material adopted by the target object. For example, “the elastic modulus of the patterned layer” denotes “the elastic modulus of the material used for the patterned layer”. Additionally, in the embodiments of the present application, material properties such as elastic modulus and tensile strength may specifically refer to the properties exhibited by the material at normal temperature, where normal temperature may be 25° C.

According to the support structure 10 provided in the embodiments of the present disclosure, the patterned layer 11 and the metal layer 12 cooperate to achieve bending and support, and the surface of the metal layer 12 distal to the patterned layer 11 is protected by the first organic layer 13, so as to reduce or avoid wrinkles or surface scratches on the metal layer 12, thereby reducing the degradation of the bending performance and structural support effect of the metal layer 12 caused by wrinkles or surface scratches, ultimately achieving a balance between the bending performance and structural support effect of the support structure. In addition, in the embodiment of the present disclosure, after forming the first organic layer 13 on the mother board of the metal layer 12, cutting is conducted to obtain multiple metal layers 12. This can prevent wrinkles or surface scratches on the metal layer 12 during the preparation process of the support structure, thus improving the material processing yield of the metal layer 12 and enhancing the mass productivity of the support structure.

The support structure 10 provided in the embodiments of the present disclosure is applicable to a foldable flexible display device. This is conducive to improving the bending performance and impact resistance of the foldable flexible display device. In the case that the openings K in the bending region 11A of the patterned layer 11 are non-through holes, the opening direction of the openings K in the bending region 11A is arranged to be consistent with the folding direction of the flexible display device to which the support structure is applied, so as to further improve the bending performance of the patterned layer 11 and the support structure 10.

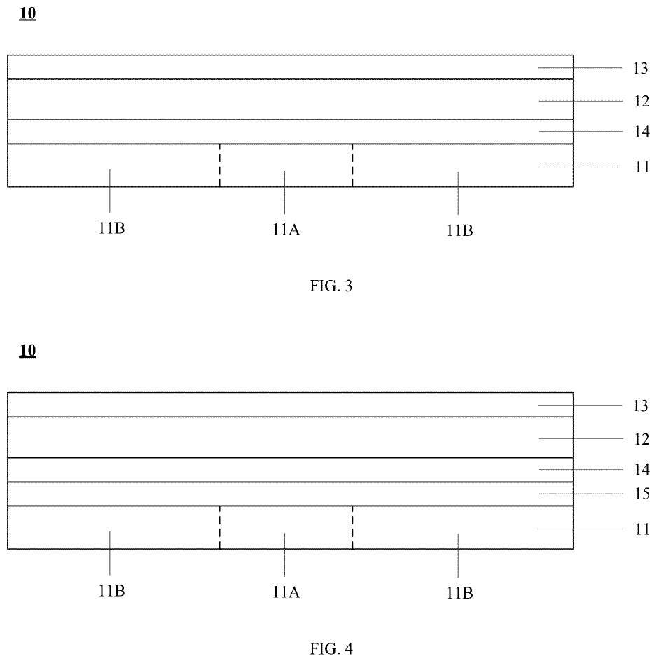

In some embodiments, FIG. 3 is a schematic cross-sectional view of another support structure according to some embodiments of the present disclosure. As shown in FIG. 3, on the basis of the support structure 10 shown in FIG. 1, the support structure 10 further includes a second organic layer 14. The second organic layer 14 is located between the patterned layer 11 and the metal layer 12. The elastic modulus of the metal layer 12 is greater than the elastic modulus of the second organic layer 14.

In some embodiments, the elastic modulus of the second organic layer 14 is greater than 10 Mpa and less than 5 Gpa.

In the embodiments of the present disclosure, by providing the organic layers on the surfaces of the two sides of the metal layer 12, respectively, the surfaces of the two sides of the metal layer 12 are protected, and the risk of wrinkles or surface scratches on the metal layer 12 is further reduced. Alternatively, in the embodiments of the present disclosure, the organic layer is provided only on the surface of one side of the metal layer 12. For example, the first organic layer 13 is provided only on a side of the metal layer 12 distal to the patterned layer 11, or the second organic layer 14 is provided only on a side of the metal layer 12 proximal to the patterned layer 11, thus protecting the metal layer 12 from scratching and wrinkling, which is not limited in the embodiments of the present disclosure.

In some embodiments, the thicknesses of the first organic layer 13, the second organic layer 14, and the metal layer 12 satisfy at least one of the following conditions: the ratio of the thickness of the first organic layer 13 to the thickness of the metal layer 12 is greater than ⅓ and less than ⅔; and the ratio of the thickness of the second organic layer 14 to the thickness of the metal layer 12 is greater than ⅓ and less than ⅔.

In some embodiments, the thickness of the second organic layer 14 is the same as or different from the thickness of the first organic layer 13. For example, the ratio of the thickness of the first organic layer 13 to the thickness of the metal layer 12 is ½, and the ratio of the thickness of the second organic layer 14 to the thickness of the metal layer 12 is also ½.

In some embodiments, the thickness of the first organic layer 13 is greater than 5 μm and less than 20 μm. The thickness of the second organic layer 14 is greater than 5 μm and less than 20 μm. For example, the thickness of the metal layer 12 is 20 μm, and the thicknesses of the first organic layer 13 and the second organic layer 14 are both 10 μm.

In the embodiments of the present disclosure, by setting the ratio of the thickness of the organic layer to the thickness of the metal layer to be greater than ⅓ and less than ⅔, the metal layer is effectively protected by the organic layer without affecting the bending performance of the metal layer as much as possible.

In some embodiments, the first organic layer 13 and the second organic layer 14 are made of an organic polymer material having an elastic modulus greater than 10 Mpa and less than 5 Gpa at a normal temperature, and such materials are characterized by low resistance to elastic deformation, so as to ensure the wrinkle resistance of the metal layer 12 and the scratch resistance of the surface of the metal layer 12. In some embodiments, the material of the first organic layer 13 includes at least one of: polymethyl methacrylate, polyimide, thermoplastic polyurethane rubber, or silicone. The material of the second organic layer 14 includes at least one of: polymethyl methacrylate, polyimide, thermoplastic polyurethane rubber, or silicone.

In some embodiments, the first organic layer 13 and the second organic layer 14 are formed by coating the surfaces of two sides of the metal layer 12 with an organic polymer material in a fluid state and then curing. For example, the metal layer 12 is a steel use stainless plate coated with an organic layer (abbreviated as Coating SUS).

In some embodiments, the material of the first organic layer 13 and that of the second organic layer 14 are the same, and accordingly, the elastic modulus of the first organic layer 13 and that of the second organic layer 14 are the same. Alternatively, the material of the first organic layer 13 and that of the second organic layer 14 may also be different, and accordingly, the elastic modulus of the first organic layer 13 and that of the second organic layer 14 are also different.

In the embodiments of the present disclosure, the patterned layer 11 and the metal layer 12 serve as support layers for supporting, and the higher the strength and the stiffness, the more likely wrinkles or surface scratches occur in the recovery process after bending compared with materials with low strength and stiffness. Therefore, in the embodiments of the present disclosure, an organic layer is employed to protect a metal layer with higher strength and stiffness, and a patterned layer with relatively low stiffness is used to make openings to form a bending region.

In some embodiments, the elastic modulus of the metal layer 12 is greater than the elastic modulus of the patterned layer 11, and/or the tensile strength of the metal layer 12 is greater than the tensile strength of the patterned layer 11.

In some embodiments, the elastic modulus of the metal layer 12 is greater than 480 Gpa and less than 1 Tpa, and the elastic modulus of the patterned layer 11 is greater than 70 Gpa and less than 150 Gpa. In some embodiments, the tensile strength of the metal layer 12 is greater than 1800 Mpa and less than 5 Gpa, and the tensile strength of the patterned layer 11 is greater than 700 Mpa and less than 2 Gpa.

In some embodiments, the material of the patterned layer 11 includes carbon fiber. The elastic modulus and/or the tensile strength of the patterned layer 11 is adjusted by adjusting the manufacturing process of the carbon fiber.

In some embodiments, the material of the metal layer 12 includes, but is not limited to, at least one of: steel use stainless, copper, or aluminum. For example, the material of the metal layer 12 is steel use stainless. The elastic modulus and/or the tensile strength of the metal layer 12 are adjusted by adjusting the material and/or the manufacturing process of the used metal, for example, the tempering temperature.

In some embodiments, the thickness of the patterned layer 11 is less than the thickness of the metal layer 12, and the weight of the patterned layer 11 is less than the weight of the metal layer 12.

In some embodiments, the patterned layer 11 and the second organic layer 14 are fixedly connected by adhesive bonding. For example, FIG. 4 is a schematic cross-sectional view of yet another support structure according to some embodiments of the present disclosure. As shown in FIG. 4, on the basis of the support structure 10 shown in FIG. 3, the support structure 10 further includes an adhesive layer 15. The adhesive layer 15 is located between the second organic layer 14 and the patterned layer 11, and is configured to fix the second organic layer 14 to the patterned layer 11 via adhesive bonding.

In some embodiments, after the first organic layer 13 and the second organic layer 14 are formed by coating the surfaces of two sides of the metal layer 12 with an organic polymer in a fluid state and then curing, a side of the second organic layer 14 distal to the metal layer 12 is bonded to the patterned layer 11 through the adhesive layer 15, thus obtaining the support structure.

In some embodiments, the adhesive layer 15 is a pressure sensitive adhesive (PSA) layer or an optical adhesive (OCA) layer. In some embodiments, the material of the adhesive layer 15 includes, but is not limited to, acryl, polyurethane (PU), or silicon-based adhesive.

In some embodiments, the elastic modulus of the adhesive layer 15 is less than 100 Kpa. The thickness of the adhesive layer 15 ranges from 10 μm to 100 μm. For example, the elastic modulus of the adhesive layer 15 is 50 Kpa, and its thickness is 20 μm. In this way, the folding requirement can be better met.

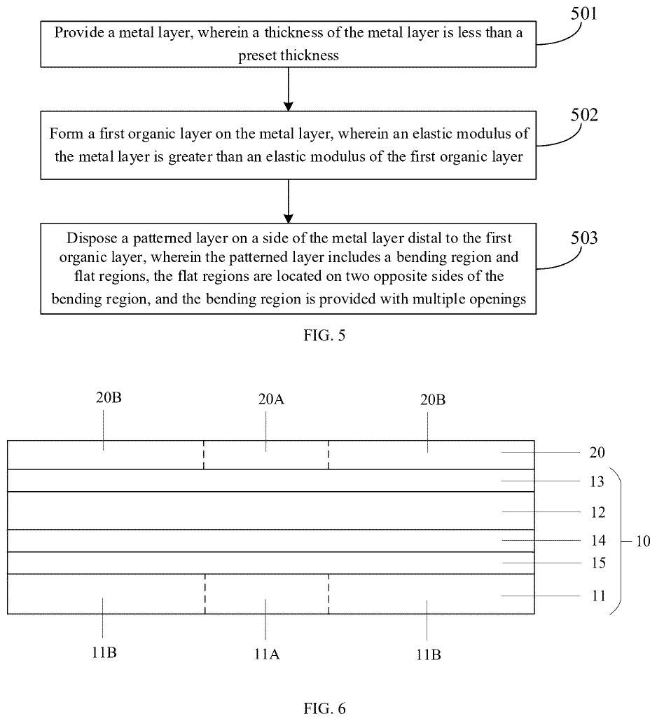

For example, FIG. 5 is a schematic flowchart of a method for manufacturing a support structure according to some embodiments of the present disclosure. The method is used to manufacture the support structure 10 shown in FIG. 1, FIG. 3, or FIG. 4. As shown in FIG. 5, the method includes, but is not limited to, the following step 501 to step 503.

In step 501, a metal layer is provided, and the thickness of the metal layer is less than a preset thickness.

In some embodiments, the thickness of the metal layer is less than 30 μm, and the elastic modulus of the metal layer is greater than 480 Gpa and less than 1 Tpa.

In step 502, a first organic layer is formed on the metal layer, and the elastic modulus of the metal layer is greater than the elastic modulus of the first organic layer.

In some embodiments, the elastic modulus of the first organic layer is greater than 10 Mpa and less than 5 Gpa.

In some embodiments, the first organic layer is formed by coating the surface of one side of the metal layer with an organic polymer material in a fluid state and then curing.

In step 503, a patterned layer is disposed on a side of the metal layer distal to the first organic layer. The patterned layer includes a bending region and a flat region, the flat region is located on two opposite sides of the bending region, and the bending region is provided with multiple openings.

In some embodiments, the patterned layer is first manufactured, and then the patterned layer is fixedly disposed on a side of the metal layer distal to the first organic layer by adhesive bonding, thus obtaining a support structure. The support structure manufactured by using above step 501 to step 503 is as shown in FIG. 1. For description of materials, functions, and the like of components in the support structure, reference may be made to related content in the above structure embodiments. Details are not described herein again in the embodiments of the present disclosure.

In some embodiments, before the patterned layer is disposed on the side of the metal layer distal to the first organic layer, a second organic layer is formed on the side of the metal layer distal to the first organic layer, and the elastic modulus of the metal layer is greater than the elastic modulus of the second organic layer. Accordingly, an implementation of disposing the patterned layer on the side of the metal layer distal to the first organic layer includes: disposing the patterned layer on a side of the second organic layer distal to the metal layer. In some embodiments, the elastic modulus of the second organic layer is greater than 10 Mpa and less than 5 Gpa. The support structure manufactured in this manner may be as shown in FIG. 3. For description of materials, functions, and the like of components in the support structure, reference may be made to related content in the above structure embodiments. Details are not described herein again in the embodiments of the present disclosure.

In some embodiments, an implementation of disposing the patterned layer on the side of the second organic layer distal to the metal layer includes: forming an adhesive layer on the side of the second organic layer distal to the metal layer, and then attaching the patterned layer on a side of the adhesive layer distal to the second organic layer. The support structure manufactured in this manner may be as shown in FIG. 4. For description of materials, functions, and the like of components in the support structure, reference may be made to related content in the above structure embodiments. Details are not described herein again in the embodiments of the present disclosure.

The support structure provided in the embodiments of the present disclosure is applicable to a foldable flexible display device to support a flexible display panel in the flexible display device in a folded state or an unfolded state. The bending region 11A of the patterned layer 11 in the support structure 10 corresponds to a bending region of the flexible display panel. The flat region 11B of the patterned layer 11 in the support structure 10 corresponds to a non-bending region of the flexible display panel. The patterned layer 11 and/or the metal layer 12 in the support structure 10 supports the flexible display panel and play a role of structural support, and is bent at the bending region.

For example, FIG. 6 is a schematic cross-sectional view of a display module according to some embodiments of the present disclosure. As shown in FIG. 6, the display module includes a flexible display panel 20 and a support structure 10. A side of the flexible display panel 20 distal to a display surface is attached to the support structure 10. The support structure 10 is configured to support and secure the flexible display panel 20 in a flattened state and a bent state.

In some embodiments, the support structure 10 is the support structure 10 shown in FIG. 1, FIG. 3, or FIG. 4, and is manufactured by the method shown in FIG. 5. In the display module shown in FIG. 6, a case in which the support structure is the support structure 10 shown in FIG. 4 is taken as an example for illustration.

Referring to FIG. 6, the flexible display panel 20 includes a bending region 20A and flat regions 20B. The orthographic projection of the bending region 11A of the patterned layer 11 in the support structure 10 on the flexible display panel 20 overlaps with the bending region 20A on the flexible display panel 20. The orthographic projection of the flat regions 11B of the patterned layer 11 in the support structure 10 on the flexible display panel 20 overlaps with the flat regions 20B on the flexible display panel 20.

The bending region 11A of the patterned layer 11 and the bending region 20A of the flexible display panel 20 are located in a bending region where the display module is bendable or foldable.

In the display module provided in the embodiments of the present disclosure, by using the support structure 10 to support and secure the flexible display panel 20 in both the flattened state and the bent state, the bending performance and impact resistance of the foldable flexible display module is improved, including increasing the number of bending cycles and service life of the display module, enhancing the drop resistance of the display module, and the like.

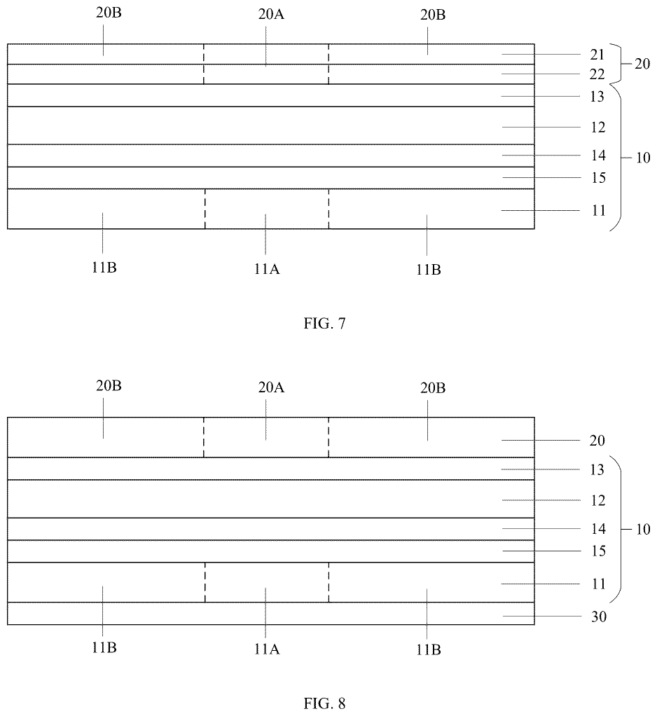

For another example, FIG. 7 is a schematic cross-sectional view of yet another display module according to some embodiments of the present disclosure. As shown in FIG. 7, the flexible display panel 20 includes a display layer 21 and a flexible base substrate 22. The patterned layer 11 is located on a side of the flexible base substrate 22 distal to the display layer 21, and the metal layer 12 in the support structure 10 is located between the patterned layer 11 and the flexible base substrate 22.

In some embodiments, the flexible display panel 20 is a flexible organic light-emitting diode (OLED) display panel or a micro light-emitting diode (Micro LED) display panel, and accordingly, the display module is a flexible OLED display module or Micro LED display module.

For example, the display layer 21 of the OLED display panel includes: a cathode, an anode, a hole injection layer (HIL), an electron injection layer (EIL), a hole transport layer (HTL), an electron transport layer (ETL), an electron blocking layer (EBL), a hole blocking layer (HBL), a light-emitting layer (EML), and the like.

In some embodiments, the material of the flexible base substrate 22 includes, but is not limited to, polyimide (PI). A thin-film transistor (TFT) array circuit is disposed on the flexible base substrate 22.

In some embodiments, the flexible display panel 20 further includes an encapsulation layer (not shown in the figure). The encapsulation layer is located on a side of the display layer 21 distal to the flexible base substrate 22. The encapsulation layer may be of a stacked structure of inorganic layer/organic layer/inorganic layer. For example, the inorganic layer/organic layer/inorganic layer may be silicon oxynitride (SiON), acryl, and silicon nitride (SiN), respectively.

In some embodiments, the display module further includes a touch layer and a protective substrate (not shown in the figure). The touch layer is located on a side of the flexible display panel 20 distal to the support structure 10, and the protective substrate is located on a side of the touch layer distal to the flexible display panel 20. The touch layer and the protective substrate may be connected by using an optical adhesive. In some embodiments, the touch layer is integrated into the flexible display panel 20. The protective substrate is a flexible foldable protective substrate. For example, the protective substrate includes at least one of a flexible film layer such as colorless polyimide (CPI) or polyethylene terephthalate (PET), or flexible ultra-thin glass (UTG).

In some embodiments, the flexible display panel 20 further includes a protective film located between the display layer 21 and the flexible base substrate 22, and a polarizer or a color film layer located between the display layer 21 and the touch layer.

In some embodiments, the flexible display panel 20 is obtained by laser cutting the display motherboard. For example, the display motherboard is cut by using a UV pico laser to obtain the flexible display panel 20.

In some embodiments, to enable the support structure 10 to better limit and support the flexible display panel 20, a limiting structure is provided in the display module. For example, FIG. 8 is a schematic cross-sectional view of yet another display module according to some embodiments of the present disclosure. As shown in FIG. 8, on the basis of the display module shown in FIG. 6, the display module further includes a limiting structure 30. The limiting structure 30 is located on a side of the support structure 10 distal to the flexible display panel 20.

The limiting structure 30 is configured to limit the screen of the display module from folding inward or folding outward. In the embodiments of the present disclosure, the flexible display panel 20 is provided with a light-emitting surface and a backlight surface that are opposite to each other. The light-emitting surface is a surface facing the user for light-emitting display. In the display module, the light-emitting surface is a surface on a side of the flexible display panel 20 facing away from the support structure 10, and the backlight surface is a surface on a side of the flexible display panel 20 facing the support structure 10. The screen being folded inward is that the screen is folded with its light-emitting surfaces facing each other, and the screen being folded outward is that the screen is folded with its light-emitting surfaces facing away from each other. For ease of distinguishing, in the embodiments of the present disclosure, the limiting structure 30 configured to limit inward folding of the screen of the display module is referred to as a first limiting structure, and the limiting structure 30 configured to limit outward folding of the screen of the display module is referred to as a second limiting structure.

In a first possible implementation, the first limiting structure is configured to limit the bending region 11A of the patterned layer 11 and the bending region 20A of the flexible display panel 20 to be in a first bent state or a flattened state. In the first bent state, light-emitting surfaces of the flat regions 20B on the two sides of the bending region 20A of the flexible display panel 20 are opposite to each other, and the angle between the flat regions 20B on the two sides is less than 180°. That is, this is equivalent to the inward-folding of the screen. In such an implementation, the elastic modulus of the second organic layer 14 is greater than the elastic modulus of the first organic layer 13.

In some embodiments, the first limiting structure is an inward-facing hinge limiting structure, which can switch between a flattened state and a state of folding toward the first direction. Wherein, the first direction refers to the stacking direction of the patterned layer 11, the metal layer 12 and the first organic layer 13. Optionally, the openings of the non-through holes in the bending region 11A of the patterned layer 11 face the first direction.

In the above first possible implementation, by setting the elastic modulus of the second organic layer 14 to be greater than the elastic modulus of the first organic layer 13, the support structure 10 is better applied to the display module with inward-folding screens. In some embodiments, the elastic modulus of the second organic layer 14 is greater than 1 Gpa and less than 5 Gpa, and the selected material includes relatively hard polymethyl methacrylate or polyimide. The elastic modulus of the first organic layer 13 is greater than 10 Mpa and less than 50 Mpa, and the selected material may include relatively soft thermoplastic polyurethane rubber or silicone.

In a second possible implementation, the second limiting structure is configured to limit the bending region 11A of the patterned layer 11 and the bending region 20A of the flexible display panel 20 to be in a second bent state or a flattened state. In the second bent state, light-emitting surfaces of the flat regions 20B on the two sides of the bending region 20A of the flexible display panel 20 face away from each other, and the included angle between the flat regions 20B on the two sides is less than 180°. That is, this is equivalent to the outward-folding of the screen. In such an implementation, the elastic modulus of the second organic layer 14 is less than the elastic modulus of the first organic layer 13.

In some embodiments, the second limiting structure is an outward-facing hinge limiting structure, which can switch between a flattened state and a state of closing toward a second direction. The second direction is opposite to the first direction. In some embodiments, the openings in the form of non-through holes in the bending region 11A on the patterned layer 11 face the second direction.

In the above second possible implementation, by setting the elastic modulus of the second organic layer 14 to be less than the elastic modulus of the first organic layer 13, the support structure 10 is better applied to the display module with outward-folding screens. In some embodiments, the elastic modulus of the second organic layer 14 is greater than 10 Mpa and less than 50 Mpa, and the selected material includes relatively soft thermoplastic polyurethane rubber or silicone. The elastic modulus of the first organic layer 13 may be greater than 1 Gpa and less than 5 Gpa, and the selected material may include relatively hard polymethyl methacrylate or polyimide.

In some embodiments, the folding region of the flexible display device is generally strip-shaped and disposed between the flat regions on the two sides. In order to adapt to the folding structure of the flexible display device, in the embodiments of the present disclosure, the shape of the bending region 11A of the patterned layer 11 in the support structure 10 is configured to be rectangular, and accordingly, the flat regions 11B are located on two sides of the long sides of the rectangle.

In the embodiments of the present disclosure, the flat regions 11B of the patterned layer 11 are disposed on two sides of the bending region 11A along the direction of the short sides of the rectangle of the bending region 11A. This is conducive to limiting and supporting the flexible display panel 20 in the case that the flexible display device is folded through the strip-shaped folding region.

The embodiments of the present disclosure further provide a display device. The display device includes any one of the above support structures, for example, the support structure 10 shown in FIG. 1, FIG. 3, or FIG. 4, or a support structure manufactured by using the method shown in FIG. 5; or the display device includes any one of the above display modules, for example, the display module shown in any one of FIG. 6 to FIG. 8.

In some embodiments, the display device includes an OLED display module.

In some embodiments, the product form of the display device includes, but is not limited to, an electronic device, such as a mobile phone, a smartwatch, a virtual reality (VR) device, a tablet computer, or a computer.

The embodiments of the present disclosure further provide an electronic device. The electronic device includes any one of the above display devices.

In some embodiments, the electronic device includes, but is not limited to, a mobile phone, a smartwatch, a VR device, a tablet computer, or a computer.

The embodiments in this specification are all described in a progressive manner, each embodiment focuses on differences from other embodiments, and reference can be made to each other for identical and similar parts between the embodiments.

In the description of this application, it should be understood that the terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, and “counterclockwise” indicate positional or locational relationships based on the positional relationships shown in the accompanying drawings. These terms are only for the convenience of describing this application and simplifying the description, and do not indicate or imply that the device or element referred to must have a specific orientation, be constructed and operated in a specific orientation, and therefore cannot be construed as limiting this application. In addition, the terms “first” and “second” are used merely for descriptive purposes and shall not be construed as indicating or implying relative importance or implicitly indicating the number of technical features indicated. Thus, a feature defined by “first” or “second” may explicitly or implicitly include one or more of such features. In the description of this application, “multiple” means two or more unless otherwise explicitly and specifically defined.

In the description of the present disclosure, it should be noted that the terms “mounted”, “connected”, and “coupled” should be understood in a broad sense unless otherwise explicitly specified and limited. For example, they may be a fixed connection, a detachable connection, or an integral connection; they may be a mechanical connection, an electrical connection, or a communication with each other; they may be directly connected, or indirectly connected through an intermediate medium, or may be internal communication between two elements or an interaction relationship between two elements. For those of ordinary skill in the art, the specific meanings of the above terms in the present disclosure can be understood according to specific circumstances.

In the present disclosure, unless otherwise explicitly specified and limited, a first feature being “on” or “under” a second feature may include the first and second features being in direct contact, or may include the first and second features not being in direct contact but being in contact through another feature therebetween. Moreover, a first feature being “on”, “above” or “over” a second feature includes the first feature being directly above and obliquely above the second feature, or simply means that the first feature is at a higher horizontal level than the second feature. A first feature being “under”, “below” or “beneath” a second feature includes the first feature being directly below and obliquely below the second feature, or simply means that the first feature is at a lower horizontal level than the second feature.

The terms “include”, “comprise”, or any other variation thereof herein are intended to encompass a non-exclusive inclusion, such that a process, method, item, or terminal device that includes a list of elements not only includes those elements, but also includes other elements not expressly listed or elements inherent to such a process, method, item, or terminal device. Without further limitation, an element defined by the phrase “including/comprising a/an . . . ” does not exclude the presence of additional identical elements in the process, method, item, or terminal device that includes the element.

In the description of the present disclosure, “multiple” refers to two or more, unless otherwise specified. Unless otherwise specified, the terms “about”, “around”, “approximately”, and the like are used for non-absolute definitions, expressing a value within ±10% of the benchmark value.

In the description of the present disclosure, unless otherwise specified, a value range represented by “between a value A and a value B” and other similar definitions includes the value A and the value B.

It should be noted that in the embodiments of the present disclosure, the word such as “exemplarily” or “for example” is used to represent that an example, an illustration, or a description is provided. Any embodiment or design scheme described as “exemplarily” or “for example” in the embodiments of the present disclosure should not be explained as being more preferred or having more advantages than other embodiments or design schemes. Specifically, the use of the word such as “exemplarily” or “for example” is intended to present a related concept in a specific manner.

In the description of the present disclosure, unless otherwise specified, “in the same layer” means that two or more defined objects are in the same layer in a stack relationship, or all or some of the objects are in the same horizontal plane in the thickness direction of the stack relationship.

The term “and/or” herein is merely a way to describe an association relationship between associated objects, indicating that there are three possible relationships. For example, “A and/or B” may represent: the existence of A alone, the simultaneous existence of A and B, and the existence of B alone.

Finally, it should also be noted that the principle and embodiments of the present disclosure are described with specific examples herein. The description of the foregoing embodiments is merely intended to help understand the technical solutions and core idea of the present disclosure. While the preferred embodiments of the present disclosure have been described, those skilled in the art can make additional variations and modifications to these embodiments once they learn of the basic inventive concepts. Therefore, it is intended that the appended claims be interpreted as including the preferred embodiments and all variations and modifications that fall within the scope of the embodiments of the present disclosure.

1. A support structure, comprising a patterned layer, a metal layer, and a first organic layer that are sequentially stacked, wherein
the patterned layer comprises a bending region and flat regions, the flat regions are located on two opposite sides of the bending region, and the bending region is provided with a plurality of openings; and
a thickness of the metal layer is less than a preset thickness, and an elastic modulus of the metal layer is greater than an elastic modulus of the first organic layer.

2. The support structure according to claim 1, wherein the thickness of the metal layer is less than 30 μm.

3. The support structure according to claim 1, wherein the elastic modulus of the metal layer is greater than 480 Gpa and less than 1 Tpa, and the elastic modulus of the first organic layer is greater than 10 Mpa and less than 5 Gpa.

4. The support structure according to claim 1, wherein the elastic modulus of the metal layer is greater than an elastic modulus of the patterned layer.

5. The support structure according to claim 4, wherein the elastic modulus of the patterned layer is greater than 70 Gpa and less than 150 Gpa.

6. The support structure according to claim 1, wherein a tensile strength of the metal layer is greater than a tensile strength of the patterned layer.

7. The support structure according to claim 6, wherein the tensile strength of the metal layer is greater than 1800 Mpa and less than 5 Gpa, and the tensile strength of the patterned layer is greater than 700 Mpa and less than 2 Gpa.

8. The support structure according to claim 1, wherein the patterned layer is made of carbon fiber.

9. The support structure according to claim 1, wherein the metal layer is made of at least one of steel use stainless, copper, or aluminum.

10. The support structure according to claim 1, wherein the first organic layer is made of at least one of polymethyl methacrylate, polyimide, thermoplastic polyurethane rubber, or silicone.

11. The support structure according to claim 1, wherein a thickness of the first organic layer is greater than 5 μm and less than 20 μm.

12. The support structure according to claim 1, further comprising a second organic layer located between the patterned layer and the metal layer; wherein
the elastic modulus of the metal layer is greater than an elastic modulus of the second organic layer.

13. The support structure according to claim 12, wherein thicknesses of the first organic layer, the second organic layer, and the metal layer satisfy at least one of following conditions:
a ratio of the thickness of the first organic layer to the thickness of the metal layer is greater than ⅓ and less than ⅔; or
a ratio of the thickness of the second organic layer to the thickness of the metal layer is greater than ⅓ and less than ⅔.

14. A display module, comprising: a flexible display panel and the support structure as defined in claim 1, wherein a side of the flexible display panel distal to a display surface is attached to the support structure;
the flexible display panel comprises a bending region and flat regions, an orthographic projection of the bending region of the patterned layer in the support structure on the flexible display panel overlaps with the bending region of the flexible display panel, and an orthographic projection of the flat regions of the patterned layer in the support structure on the flexible display panel overlaps with the flat regions on the flexible display panel.

15. The display module according to claim 14, wherein the flexible display panel comprises a display layer and a flexible base substrate;
the patterned layer is located on a side of the flexible base substrate distal to the display layer, and a metal layer in the support structure is located between the patterned layer and the flexible base substrate.

16. The display module according to claim 15, further comprising a first limiting structure located on a side of the support structure distal to the flexible display panel; wherein
the first limiting structure is configured to limit the bending region of the patterned layer and the bending region of the flexible display panel to be in a first bent state or a flattened state;
in the first bent state, light-emitting surfaces of the flat regions on two sides of the bending region of the flexible display panel are opposite to each other, and an angle between the flat regions on the two sides is less than 180°; and
the support structure comprises the patterned layer, a second organic layer, the metal layer, and the first organic layer that are sequentially stacked, and an elastic modulus of the second organic layer is greater than the elastic modulus of the first organic layer.

17. The display module according to claim 15, further comprising a second limiting structure located on a side of the support structure distal to the flexible display panel; wherein
the second limiting structure is configured to limit the bending region of the patterned layer and the bending region of the flexible display panel to be in a second bent state or a flattened state;
in the second bent state, light-emitting surfaces of the flat regions on two sides of the bending region of the flexible display panel are opposite to each other in a back-to-back manner, and an angle between the flat regions on the two sides is less than 180°; and
the support structure comprises the patterned layer, a second organic layer, the metal layer, and the first organic layer that are sequentially stacked, and an elastic modulus of the second organic layer is less than the elastic modulus of the first organic layer.

18. A display device, comprising a support structure; wherein the support structure comprises a patterned layer, a metal layer, and a first organic layer that are sequentially stacked, wherein
the patterned layer comprises a bending region and flat regions, the flat regions are located on two opposite sides of the bending region, and the bending region is provided with a plurality of openings; and
a thickness of the metal layer is less than a preset thickness, and an elastic modulus of the metal layer is greater than an elastic modulus of the first organic layer.

19. The display device according to claim 18, wherein the elastic modulus of the metal layer is greater than an elastic modulus of the patterned layer.

20. The display device according to claim 18, wherein a tensile strength of the metal layer is greater than a tensile strength of the patterned layer.
